(19) United States
(12) Patent Application Publication
(10) Pub. No.: US 2023/0234182 A1
(43) Pub. Date: Jul. 27, 2023

(54) CHUCK TABLE AND GRINDING APPARATUS

(71) Applicant: DISCO CORPORATION, Tokyo (JP)

(72) Inventor: Masaru NAKAMURA, Tokyo (JP)

(21) Appl. No.: 18/150,405

(22) Filed: Jan. 5, 2023

(30) Foreign Application Priority Data
Jan. 26, 2022 (JP) 2022-010251

(51) Int. Cl. B24B 41/06

(52) U.S. Cl. CPC B24B 41/068

(57) ABSTRACT

A grinding apparatus includes a chuck table for holding a wafer, a grinding unit including, in a rotatable manner, a grinding wheel on which a plurality of grindstones for grinding the wafer held by the chuck table are disposed in an annular pattern, and a grinding water supply unit for supplying grinding water to the grindstones and the wafer. The chuck table includes a porous plate having a holding surface for holding the wafer under suction and a frame body that supports an outer periphery and a bottom surface of the porous plate and transmits a negative pressure and a positive pressure to the holding surface, and the frame body is formed with a plurality of grooves extending from the holding surface side to a side surface.

### BACKGROUND OF THE INVENTION

### Field of the Invention

The present invention relates to a chuck table for holding a wafer and a grinding apparatus for grinding the wafer held by the chuck table.

### Description of the Related Art

A wafer formed on a front surface thereof with a plurality of devices such as integrated circuits (ICs) or large-scale integration (LSI) circuits partitioned by a plurality of intersecting planned dividing line (streets) is ground at a back surface thereof by a grinding apparatus to be formed into a desired thickness, and is thereafter divided into individual device chips by a dicing apparatus or a laser processing apparatus, and the divided device chips are used for electric apparatuses such as mobile phones and personal computers.

The grinding apparatus includes a chuck table that holds the wafer, a grinding unit including, in a rotatable manner, a grinding wheel on which a plurality of grindstones for grinding the wafer held by the chuck table are disposed in an annular pattern, and a grinding water supply unit that supplies grinding water to the grindstones and the wafer, and is capable of processing the wafer to a desired thickness (refer to, for example, Japanese Patent Laid-open No. 2009-246098).

### SUMMARY OF THE INVENTION

Incidentally, when the wafer held by the chuck table is ground in the above-described grinding apparatus, contaminants (grinding swarf) generated during grinding mix into the grinding water supplied during grinding, and the grinding water containing the contaminants stagnates in the periphery of the chuck table, so that there is a problem that, at the time when the wafer is conveyed out of the chuck table, a suction pad of a conveying mechanism sucks in the contaminants and is thereby contaminated.

In addition, there is a problem that, at the time when the chuck table holds a next wafer under suction, the chuck table sucks in the grinding water containing the contaminants mixed therein and a porous plate constituting the chuck table is thereby clogged.

Accordingly, it is an object of the present invention to provide a chuck table and a grinding apparatus by which it is possible to dissolve the problem that a suction pad of a conveying mechanism sucks in contaminants to be thereby contaminated and the problem that a porous plate is clogged.

In accordance with an aspect of the present invention, there is provided a chuck table for holding a wafer. The chuck table includes a porous plate that has a holding surface for holding the wafer under suction, and a frame body that supports an outer periphery and a bottom surface of the porous plate and transmits a negative pressure and a positive pressure to the holding surface. The frame body is formed with a plurality of grooves extending from the holding surface side to a side surface.

In accordance with another aspect of the present invention, there is provided a grinding apparatus including a chuck table for holding a wafer, a grinding unit including, in a rotatable manner, a grinding wheel on which a plurality of grindstones for grinding the wafer held by the chuck table are disposed in an annular pattern, and a grinding water supply unit for supplying grinding water to the grindstones and the wafer. The chuck table includes a porous plate having a holding surface for holding the wafer under suction and a frame body that supports an outer periphery and a bottom surface of the porous plate and that transmits a negative pressure and a positive pressure to the holding surface, and the frame body is formed with a plurality of grooves extending from the holding surface side to a side surface.

According to the chuck table of the present invention, when the chuck table of the present invention is applied to the grinding apparatus, the grinding water containing contaminants or the like mixed therein smoothly flows down from an outer periphery of the chuck table, that is, an upper surface of the frame body, due to capillary phenomenon in the grooves and the surface tension of the grinding water flowing down from the side surface of the frame body, so that the grinding water is restrained from stagnating in the outer periphery of the chuck table. As a result, the problem that, when the processed wafer is conveyed out of the chuck table, the suction pad for holding the wafer under suction sucks in contaminants or the like generated during processing and is thereby contaminated is dissolved.

According to the grinding apparatus of the present invention, the grinding water containing contaminants or the like mixed therein smoothly flows down from the outer periphery of the chuck table, that is, the upper surface of the frame body, due to capillary phenomenon in the grooves formed in the frame body and the surface tension of the grinding water flowing down from the side surface of the frame body, so that the grinding water is restrained from stagnating in the outer periphery of the chuck table. As a result, the problem that, when the ground wafer is conveyed out of the chuck table, the suction pad for holding the wafer under suction sucks in the contaminants or the like generated during processing and is thereby contaminated is dissolved.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a wafer held by a chuck table according to an embodiment of the present invention;

FIG. 2 is a perspective view of the whole part of a grinding apparatus according to the embodiment of the present invention;

FIG. 3 is a perspective view depicting the manner of holding the wafer on the chuck table of the grinding apparatus depicted in FIG. 2;

FIG. 4 is a sectional view depicting the manner of connecting a suction source, a water source, and an air supply source to the chuck table depicted in FIG. 2; and

FIG. 5 is a perspective view depicting the manner in which the wafer is ground in the grinding apparatus depicted in FIG. 2.

### DETAILED DESCRIPTION OF THE PREFERRED EMBODIMENT

A chuck table according to an embodiment of the present invention and a grinding apparatus for grinding a wafer held by the chuck table will be described in detail below with reference to the attached drawings.

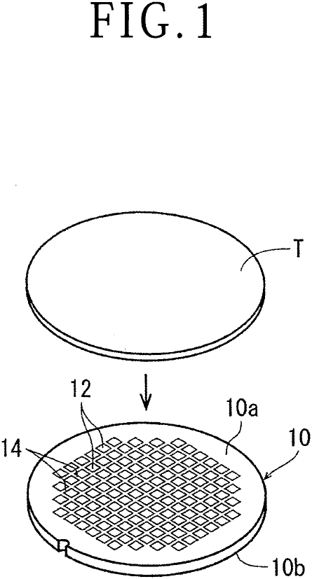

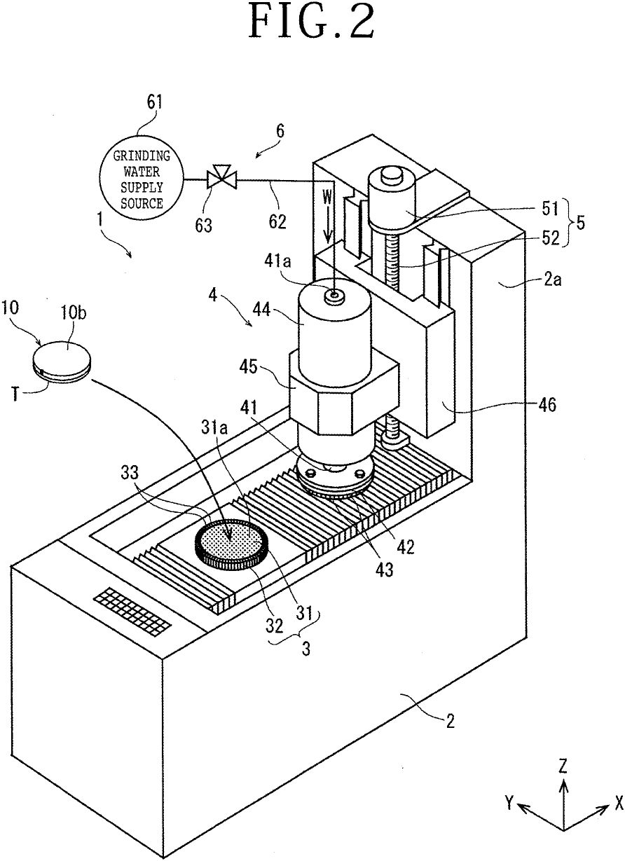

FIG. 1 depicts a wafer 10 which is held by a chuck table 3 of a grinding apparatus 1 (see FIG. 2) of the present embodiment and ground. The wafer 10 is formed on a front surface 10a thereof with a plurality of devices 12 partitioned by a plurality of intersecting streets 14, and a protective tape T is adhered to the front surface 10a at the time of grinding of the wafer 10.

FIG. 2 depicts a perspective view of the whole part of the grinding apparatus 1 that grinds the wafer 10 according to the present embodiment. The grinding apparatus 1 includes at least the chuck table 3 for holding the wafer 10, a grinding unit 4 that grinds a back surface 10b of the wafer 10 held by the chuck table 3, a lifting and lowering mechanism 5 that lifts and lowers the grinding unit 4 in a Z-axis direction (vertical direction), and a grinding water supply unit 6 that supplies grinding water W to grindstones 43 of the grinding unit 4 and the wafer 10.

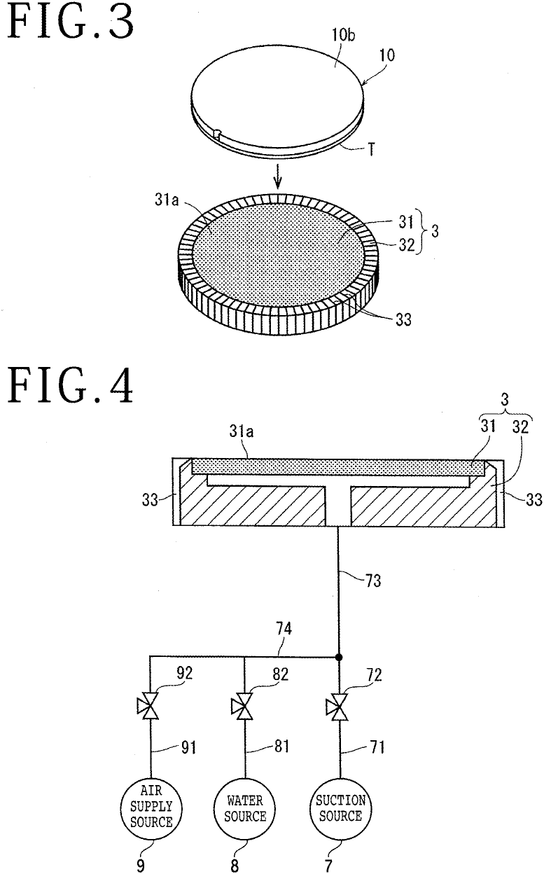

As understood from FIGS. 2 and 3, the chuck table 3 includes a porous plate 31 having a holding surface 31a for holding the wafer 10 under suction and a frame body 32 that supports an outer periphery and a bottom surface of the porous plate 31 and that transmits a negative pressure and a positive pressure to the holding surface 31a. The porous plate 31 is formed from a gas-permeable member. The frame body 32 is formed over the whole circumference thereof with a plurality of grooves 33 extending from the holding surface 31a side to a side surface. The width of each of the grooves 33 is on the order of, for example, 1 to 2 mm.

The chuck table 3 is configured to be rotatable by an unillustrated rotational drive mechanism, and is moved by an unillustrated X-axis moving means mechanism accommodated inside an apparatus housing 2 to desired positions in the X-axis direction, for example, a conveying-in/conveying-out position for conveying-in and conveying-out of the wafer 10 on the viewer’s side of the figure and a grinding position where grinding is conducted directly under the grinding unit 4.

As depicted in FIG. 4, to the frame body 32, a suction source 7 is connected through a communication passage 73 and a communication passage 71, a water source 8 is connected through the communication passage 73 and communication passages 74 and 81, and an air supply source 9 is connected through the communication passages 73 and 74 and a communication passage 91. An on-off valve 72 is disposed in the communication passage 71, an on-off valve 82 is disposed in the communication passage 81, and an on-off valve 92 is disposed in the communication passage 91. By closing the on-off valves 82 and 92, opening the on-off valve 72, and operating the suction source 7, a negative pressure can be transmitted through the frame body 32 and generated on the holding surface 31a of the porous plate 31. In addition, by closing the on-off valves 72 and 92, opening the on-off valve 82, and operating the water source 8, cleaning water can be supplied through the frame body 32 and jetted to the holding surface 31a of the porous plate 31. Further, by closing the on-off valves 72 and 82, opening the on-off valve 92, and operating the air supply source 9, a positive pressure can be transmitted through the frame body 32 and generated on the holding surface 31a of the porous plate 31. Moreover, by closing the on-off valve 72, opening the on-off valves 82 and 92, and operating the water source 8 and the air supply source 9, a mixed fluid of air and water can be jetted to the holding surface 31a of the porous plate 31.

As depicted in FIG. 2, the grinding unit 4 includes at least a rotary shaft 41, a grinding wheel 42 disposed at a lower end of the rotary shaft 41, a plurality of the grindstones 43 disposed in an annular pattern on a lower surface of the grinding wheel 42, an electric motor 44 for rotating the rotary shaft 41, a support section 45 that supports the grinding unit 4, and a Z-axis moving base 46 supported in such a manner as to be liftable and lowerable in the Z-axis direction together with the support section 45. The lifting and lowering mechanism 5 can convert a rotational motion of a pulse motor 51 into a rectilinear motion and transmit the rectilinear motion to the Z-axis moving base 46 through a ball screw 52 rotated by the pulse motor 51, and can move the grinding unit 4 to a desired position in the Z-axis direction (vertical direction). The grinding water supply unit 6 includes a grinding water supply source 61, a communication passage 62, and an on-off valve 63 for opening and closing the communication passage 62, and the communication passage 62 is connected to an upper end 41a of the rotary shaft 41 of the grinding unit 4. The grinding water W supplied from the grinding water supply source 61 passes through the inside of the rotary shaft 41, to be supplied to the wafer 10 held by the chuck table 3 and the grindstones 43 for grinding the wafer 10. The grinding apparatus 1 includes an unillustrated controller, and the above-mentioned operating sections are controlled by control signals transmitted from the controller.

The grinding apparatus 1 and the chuck table 3 according to the present embodiment are substantially configured as above-described, and the functions and actions thereof will be described below.

In grinding the back surface 10b of the wafer 10 by the above-described grinding apparatus 1, the chuck table 3 is moved to the conveying-in/conveying-out position, and the wafer 10 is mounted on the holding surface 31a of the chuck table 3, with the back surface 10b side directed upward and with the protective tape T side directed downward, as depicted in FIG. 2. Next, the on-off valve 72 described based on FIG. 4 is opened and the suction source 7 is operated, to generate a negative pressure on the holding surface 31a of the porous plate 31, whereby the wafer 10 is held under suction.

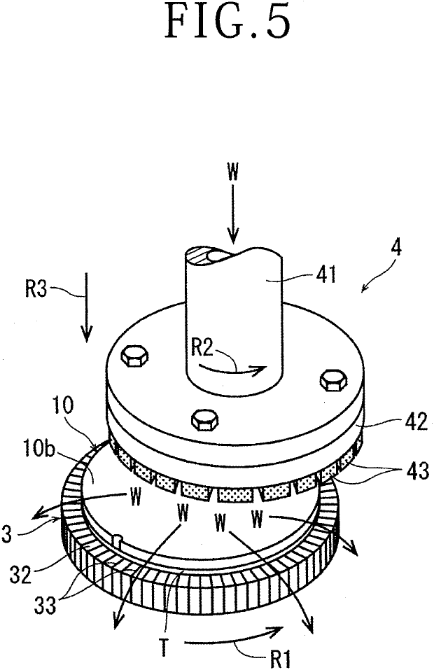

Subsequently, the above-mentioned X-axis moving means mechanism is operated to position the chuck table 3 at the grinding position directly under the grinding unit 4. Then, as depicted in FIG. 5, the chuck table 3 is rotated at a predetermined rotational speed (for example, 300 rpm) in a direction indicated by an arrow R1, by operating the unillustrated rotational drive mechanism, and the rotary shaft 41 of the grinding unit 4 is rotated at a predetermined rotational speed (for example, 3,000 rpm) in a direction indicated by an arrow R2. Next, the above-mentioned lifting and lowering mechanism 5 is operated to lower the grinding unit 4 in a direction indicated by an arrow R3, to thereby bring the grindstones 43 into contact with the back surface 10b of the wafer 10, and the above-mentioned grinding water supply unit 6 is operated to supply the grinding water W to the grindstones 43 and the back surface 10b of the wafer 10 through the rotary shaft 41. In this way, while the grinding unit 4 is put into grinding feeding at a predetermined speed (for example, 1 µm/sec), the wafer 10 is ground and thinned to a predetermined thickness. Note that, in conducting the grinding, an unillustrated thickness measuring device may be operated, whereby the grinding can be conducted while the thickness of the wafer 10 is measured.

When the grinding is conducted by the grinding apparatus 1 according to the present embodiment, since the frame body 32 of the chuck table 3 is formed with the plurality of grooves 33 extending from the holding surface 31a side to the side surface, the grinding water W that is supplied to the grindstones 43 and the wafer 10 and that contains contaminants mixed therein smoothly flows down from the outer periphery of the chuck table 3, that is, from the upper surface of the frame body 32, due to capillary phenomenon in the grooves 33 and the surface tension of the grinding water W flowing down from the side surface of the frame body 32, so that the grinding water W is restrained from stagnating in the outer periphery of the chuck table 3. As a result, the problem that, when the operation of the suction source 7 is stopped and the wafer 10 is conveyed out of the chuck table 3 after the grinding, an unillustrated suction pad sucks in the contaminants and is thereby contaminated is dissolved.

When the above-mentioned grinding is finished, the above-mentioned on-off valves 72 and 92 are closed, the on-off valve 82 is opened, and the water source 8 is operated to jet cleaning water from the holding surface 31a of the porous plate 31 and clean the porous plate 31. Alternatively, the on-off valve 72 is closed, the on-off valves 82 and 92 are opened, and the water source 8 and the air supply source 9 are operated to jet a mixed fluid of air and water to the holding surface 31a of the porous plate 31 and clean the porous plate 31. Then, the on-off valves 72 and 82 are closed, the on-off valve 92 is opened, and the air supply source 9 is operated to supply drying air to the porous plate 31 and dry the porous plate 31. In this instance, also, since the frame body 32 of the chuck table 3 is formed with the above-mentioned grooves 33, the cleaning water jetted from the inside of the frame body 32 to the holding surface 31a side of the porous plate 31 cleans the porous plate 31 and smoothly flows down to the outside of the frame body 32, so that the cleaning water is restrained from stagnating on the frame body 32, and the problem that, when the porous plate 31 of the chuck table 3 holds a next wafer 10 under suction, the porous plate 31 sucks in the water containing contaminants or the like and stagnating on the frame body 32 and is thereby clogged is dissolved.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A chuck table for holding a wafer, the chuck table comprising:
a porous plate that has a holding surface for holding the wafer under suction; and
a frame body that supports an outer periphery and a bottom surface of the porous plate and transmits a negative pressure and a positive pressure to the holding surface,
wherein the frame body is formed with a plurality of grooves extending from the holding surface side to a side surface.

2. A grinding apparatus comprising:
a chuck table for holding a wafer;
a grinding unit including, in a rotatable manner, a grinding wheel on which a plurality of grindstones for grinding the wafer held by the chuck table are disposed in an annular pattern; and
a grinding water supply unit for supplying grinding water to the grindstones and the wafer,
wherein the chuck table includes a porous plate having a holding surface for holding the wafer under suction and a frame body that supports an outer periphery and a bottom surface of the porous plate and that transmits a negative pressure and a positive pressure to the holding surface, and
the frame body is formed with a plurality of grooves extending from the holding surface side to a side surface.
